(19) United States
(12) Patent Application Publication
(10) Pub. No.: US 2022/0291303 A1
(43) Pub. Date: Sep. 15, 2022

(54) PROCESS FOR ESTIMATING THE RESIDUAL LIFE OF THE ELECTROMAGNET OF A VIBRATING FEEDER OF ARTICLES

(71) Applicant: BROVIND VIBRATORI S.P.A., Cortemilia (IT)

(72) Inventors: Paolo REOLFI, Cortemilia (IT); Daniele Icardi, Cortemilia (IT); Simone Tagliero Cinquanta, Cortemilia (IT)

(73) Assignee: BROVIND VIBRATORI S.P.A., Cortemilia (IT)

(21) Appl. No.: 17/639,801

(22) PCT Filed: Sep. 4, 2020
(86) PCT No.: PCT/IT2020/050215

§ 371 Date: Mar. 2, 2022

(30) Foreign Application Priority Data
Sep. 6, 2019 (IT) 102019000015734

(51) Int. Cl. G01R 33/07; G01R 27/14

(52) U.S. Cl. CPC G01R 33/07; G01R 27/14; B65G 27/24

(57) ABSTRACT

A process for estimating the residual life of an electromagnet of a vibrating feeder of articles is described, controlled through a control circuit to make at least one element of the feeder vibrate in frequency, the process comprising the following phases: constantly monitoring the waveform of the absorbed current (I) and the operating voltage (V) to calculate an ohmic resistance value to be compared with a reference value; comparing the measurement of the density of a magnetic flux (Bm) with respect to a reference saturation limit value (Bsat), using an inductance value (L) based on the acquisition of the absorbed current (I) value; verifying an efficient operating situation of the vibrating feeder through the condition (ε1=Bₘ−Bₛₐₜ<0).

The present invention refers to a procedure for estimating the residual life of the electromagnet of a vibrating feeder of articles.

In general, the present invention relates to error monitoring and detection, control means, display, regulation or control units, arrangements for conditioning or analyzing measured signals, e.g. to indicate peak values, details related to sampling, digitizing or capturing the waveform, short circuit test, indication that the current or voltage is above or below a predetermined value or within or outside a predetermined range of values, characterized by alternating or direct current application of voltage or current in AC supplies, arrangements for measuring electrical power or power factor by measuring current and voltage.

In particular, the present invention relates to armature tests or field windings, arrangements for monitoring electrical energy systems, e.g. power lines or loads, recording, testing of electrical equipment, lines or components, for short circuits, discontinuity, current leakage or incorrect line connection, short circuit, leakage or earth fault test, measurement of actual values, or mean square values, measurement of peak values or amplitude or envelope of AC or pulses, measurement power factor, test of dynamo-electric machines in operation, test or electrical monitoring by means of a monitoring system capable of detecting and responding to failures characterized by the process fault detection by injecting test signals and analyzing the monitored process response, e.g. inject the test signal while the normal operation of the monitored system is interrupted, superposition of the test signal on a control signal during normal operation of the monitored system.

Since the first application of power supply systems based on vibrating drives, it has been necessary to use electronic control devices capable of transforming the mains voltage into a suitable sinusoidal signal capable of appropriately controlling the appliance according to the desired mechanical resonance frequency and the power to be delivered, in order to obtain the desired speed of movement of the parts inside the containers.

Over time, these electronic devices in addition to carrying out the control functions, have also begun to perform similarly communication functions, reading signals from external sensors and/or sending their operating parameters to central units such as, for example, PLC, and control in order to monitor the efficiency of the system itself and to be able to check the operating status of the vibrating units.

Historically, this feedback derives from a suitable sensor/transducer, an accelerometer with the main purpose of standardizing and controlling the command signal given to the vibrating drive in a closed loop. Therefore, an important element in the correct monitoring of such a power supply system is missing, namely diagnostics.

The main heart of a vibrating drive is in fact the magnetic coil subjected inside it to a suitable command signal, for example, sinusoidal reconstructed through PWM, in order to attract an armature to itself; this periodic attraction/release, through suitable elastic elements suitably sized and positioned, generates an oscillating movement, which allows the parts to move forward.

At present, the different stresses experienced by a coil crossed by a current are unknown; according to the label data provided by the manufacturer of the reels, the electronic control systems can be suitably parameterized so as not to operate outside the given working curve, but, during the actual application, it is always possible, even just for a few minutes, to exceed these thresholds unwittingly and above all without having any return on the matter, thus affecting the ideal life cycle of the coils with the risk of a short circuit.

Then there is always the discrepancy between the ideal declared values of a coil and any defects in the manufacturing process that lead to a very different life cycle of the coils.

U.S. Pat. No. 9,886,835 B2 relates to a process for estimating a residual life of a coil of a solenoid of a valve controller operating in a process control system, the process comprising the steps of recording a duration of activation of the solenoid coil during operation of the solenoid coil, determining an operating temperature of the solenoid coil, estimating the remaining life of the solenoid coil based on the duration of the activation of the solenoid coil and the operating temperature of the solenoid coil.

The process includes keeping a record of a solenoid coil activation duration, determining a solenoid coil operating temperature, generating an estimate of the remaining life of the solenoid coil based on the duration of the coil activation of the solenoid and the operating temperature of the solenoid coil. The process may further comprise, in any combination, maintaining the solenoid coil on duration record including storing a solenoid coil on duration value, starting a timer when the solenoid coil is on and increasing the value of the on duration of the solenoid coil based on the timer.

Determining the operating temperature of the solenoid coil involves obtaining a measurement of the operating temperature of the solenoid coil with a temperature sensor, estimating the residual life of the solenoid coil is to determine, based on the operating temperature, a duration expected average of a solenoid coil insulation, a residual life of the solenoid coil by subtracting the on time of the solenoid coil from the expected average life of the solenoid coil insulation.

The comparison of the estimate of the residual life of the solenoid coil with respect to a threshold value allows to generate an alarm indication.

Determination of the operating temperature of the solenoid coil and estimation of the remaining life of the solenoid coil is performed periodically during the operation of the solenoid coil.

Detecting an impending solenoid coil failure and generating an alarm indication in response to the detection of an impending solenoid coil failure is based on measuring a current draw of the solenoid coil, including inrush current, via an electronic form.

In particular, the state of the art is represented by the following documents: US 2001/0043450 A1; U.S. Pat. Nos. 6,208,497 B1; 5,602,711A; 5,467,244 A; US 2007/0030619 A1; U.S. Pat. No. 4,652,820 A.

U.S. Pat. No. 9,886,835 B2 offers the starting point for estimating a residual life of a coil of a solenoid before the magnetic saturation of the coil itself.

Object of the present invention is solving the aforementioned prior art problems by providing an alternative process to the processes known from the state of the art to estimate the useful life of a reel of a vibrating feeder of articles.

A further object is to create a database with the information of magnetic quantities in order to optimize the operating and calibration conditions of a vibrating article feeder.

The aforementioned and other purposes and advantages of the invention, which will emerge from the following description, are achieved with a procedure for estimating the residual life of the electromagnet of a vibrating feeder of articles as described in the independent claims. Preferred embodiments and non-trivial variants of the present invention form the subject matter of the dependent claims.

It is understood that all the attached claims form an integral part of the present description.

It will be immediately obvious that innumerable variations and modifications (for example relating to shape, dimensions, arrangements and parts with equivalent functionality) can be made to what has been described without departing from the scope of the invention as appears from the attached claims.

The present invention will be better described by some preferred embodiments, provided by way of non-limiting example, with reference to the attached drawings, in which:

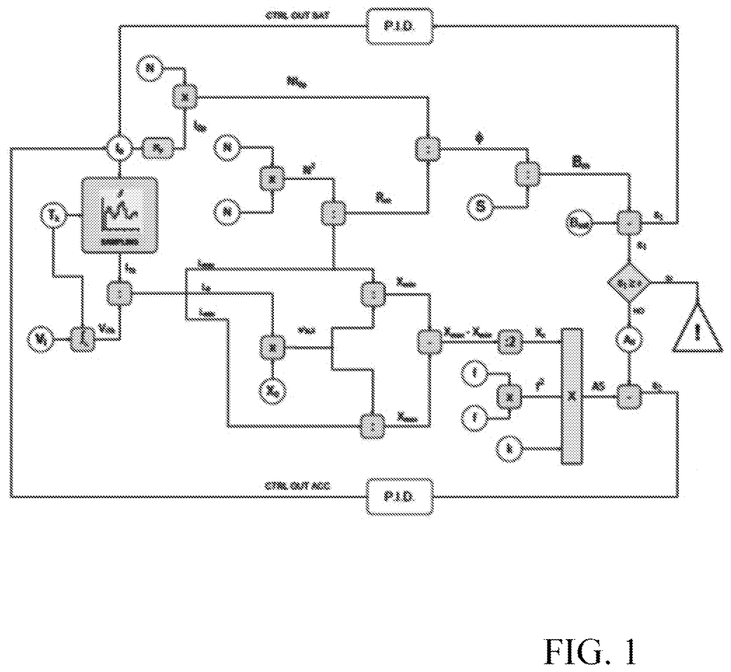

FIG. 1 shows a conceptual model of a first functional diagram of an implementation of the procedure for estimating the residual life of the electromagnet of a vibrating feeder of articles according to the present invention;

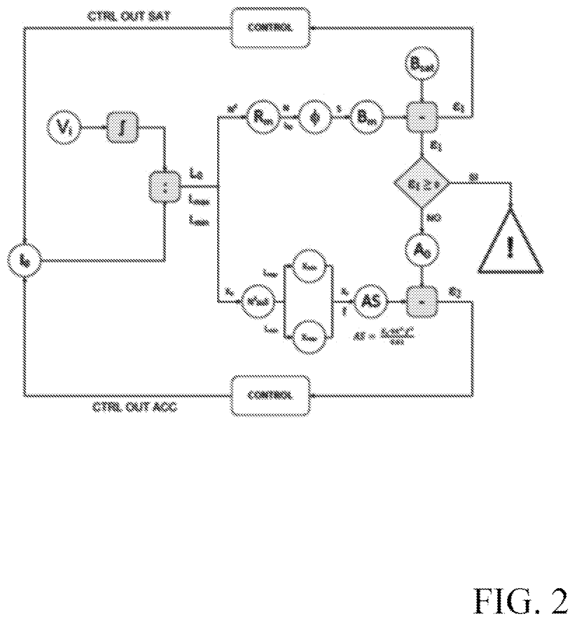

FIG. 2 shows a physical model of the previous figure;

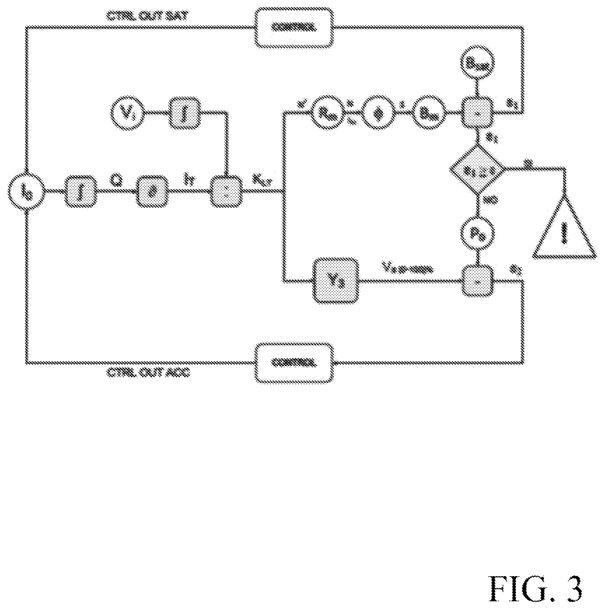

FIG. 3 shows a conceptual model of a second functional scheme of an implementation of the procedure for estimating the residual life of the electromagnet of a vibrating feeder of articles according to the present invention;

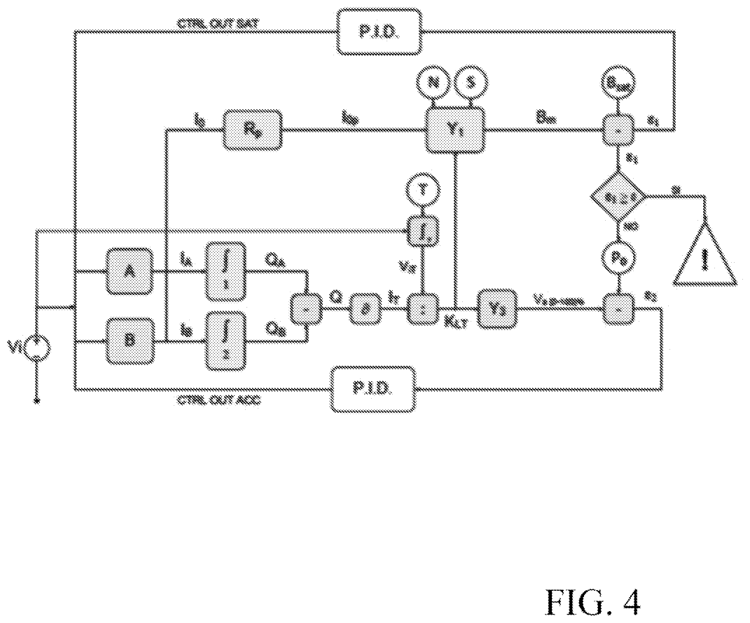

FIG. 4 shows a first functional model of the previous figure; and

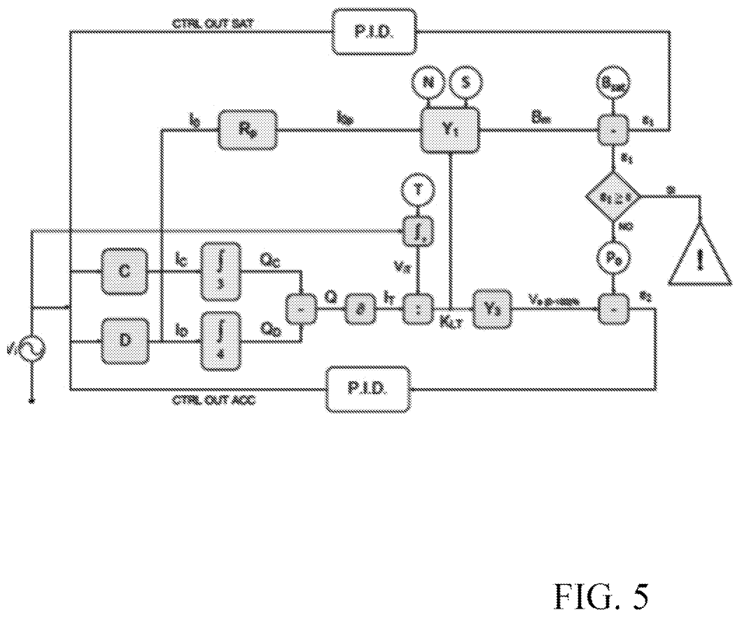

FIG. 5 shows a second functional model of FIG. 3.

Referring to the figures, it is possible to note that a vibrating feeder of articles comprises at least one electromagnet controlled by a control circuit to make at least one element of the feeder vibrate in frequency. The control circuit can be of the fixed or multiple channel type, fixed or variable frequency. In particular, the control circuit includes a Hall effect sensor, a differential amplifier, a comparator, and an integration circuit for controlling the speed and displacement of the power supply element.

Advantageously, the control circuit comprises a dedicated stage adapted to maintain a galvanic separation between a high voltage part where measured electric current flows and a low voltage part of a signal processed to measure, moment by moment, the absorbed current and the operating voltage of the electromagnet.

A process of estimating the residual life of at least one electromagnet of a vibrating article feeder comprises the following steps:
constantly monitoring the waveform of the absorbed current I and the operating voltage V to calculate an ohmic resistance value of the electromagnet, to be compared with a reference value;
determining a residual margin before the magnetic saturation of the electromagnet;
determining an appropriate air gap;
comparing the measurement of the density of a magnetic flux Bm with respect to a reference saturation limit value Bsat on the basis of the saturation of the absorbed current I value;
verifying an efficient operating situation of the vibrating feeder through the condition ε₁=Bₘ−Bₛₐₜ<0.

The value of the inductance L on the basis of the acquisition of the absorbed current value I is obtained by:
sampling an electrical current signal I0 with a period Tk;
calculating the inductance L given by the ratio between the integral of the supply voltage, ViTk, and the amplitude of a current sample ITk, the integral of the supply voltage ViTk calculated between the start of the measurement, t=0, and the instant to which the sampling refers, t=t0, with t0∈Tk, the amplitude of the current sample ITk referred to the instant t=t0, with t0∈Tk, the inductance L defined punctually and, starting from a constant value L0, corresponding to the manually set air gap, able to vary between a minimum value Lmin, at maximum air gap, and a maximum value Lmax, at minimum air gap, during the normal harmonic oscillation of the electromagnet in the vibrating feeder.

Alternatively, referring to FIGS. 4, 5, the value of the inductance L on the basis of the acquisition of the absorbed current value I is obtained by:
calculating the average inductance KLT in a period T given by the ratio between the integral of the supply voltage ViT and the intensity of current IT, the constant supply voltage Vi, if applied to the input of a pulse width modulator AB, of a circuit that has a PWM, which uses IGBT, the variable supply voltage Vi, if applied at the input to a phase shifter CD, which uses TRIAC, distinguishing between the intensity of current supplied by the electrical network to the coil of the electromagnet, IA or IC, and the intensity of current released by the coil in the electromagnet to the mains, IB or ID, distinguishing between the quantity of electric charge supplied by the mains to the coil in the electromagnet, QA or QC, integrating the signal current, IA or IC, in the half-period [0; T/2] and the quantity of electric charge released in the electromagnet to the mains, QB or QD, integrating the current signal, IB or ID, in the half-period [T/2; T], the difference between the two quantities of electric charge thus calculated, Q=QA−QB or Q=Qc−QD, being responsible for the actual movement of the vibrating and loss generating unit mechanical and magnetic, the intensity of current IT responsible for the effective movement of the vibrating unit and generating mechanical and magnetic losses, obtained with an operation of derivation in the period T of the quantity of effective electric charge Q.

From an operational point of view, the procedure takes place according to the following phases:

a) starting the power supply;
b) automatically controlling in negative feedback the waveform trend of the absorbed current I;
c) in the event of an anomaly signaled by the reaching and possible exceeding of a threshold value, for which the residual margin ε₁ before the magnetic saturation of the electromagnet is not respected, stopping the power supply;
d) controlling the gap distance;
e) restarting the power supply;
f) automatically controlling in negative feedback the waveform trend of the absorbed current I;
g) in the event of an anomaly signaled by the achievement and eventual exceeding of a threshold value, for which the residual margin ε₁ before the magnetic saturation of the electromagnet is not respected, stopping the power supply;
h) replacing the reel body;
i) restarting the power supply;
j) automatically controlling in negative feedback the waveform trend of the absorbed current I;
k) in case of efficient operation, identification of the correspondence between the electrical power involved and the indication of the density with which the magnetic flux is distributed in the magnetic path inside the electromagnet, in relation to the consumption of the absorbed current I;
l) controlling all planned diagnostic activities, such as integration of electromagnetic diagnostic procedures and monitoring of mechanical parameters, channel acceleration and operating frequency, to allow the operator to set the normal variation of the acceleration parameter a0.

A negative feedback control to maintain an acceleration parameter aS with respect to the acceleration parameter a0 is set manually, until the appropriate alarm signal is issued, upon reaching the electromagnet's magnetic saturation condition.

The procedure is carried out without sensors or other means of direct detection of the magnetic field flux or the acceleration value to which the vibrating feeder is subjected. In this case, the process is carried out through numerical processing of a microprocessor or through an electronic circuit with discrete components.

Alternatively, it is possible to use sensors or other detection means such as Hall effect probes, capable of directly measuring the magnetic field flux and thus allowing to obtain a comparison between Bm and Bsat, accelerometers capable of directly measuring the acceleration value at to which the vibrating feeder is subjected through which it is possible to obtain L itself, a sensor used to measure the displacement of the moving components of the vibrating feeder, an instantaneous measurement and an average measurement over the period of I.

A computer program is provided comprising computer program code means suitable for carrying out all or part of the steps of the process, in the case of a program executed on a computer any control system for vibratory feeders, such as a dedicated controller, an operator panel, a PLC, a computer or any means suitable to implement such a program. The computer program is contained on a support that can be read by any control system for vibratory feeders, such as a dedicated controller, an operator panel, a PLC, a computer or any means suitable for implementing this program.

The innovation presented here therefore consists in the implementation of a sensor inside the control system capable of monitoring in real time the various parameters inherent to the passage of an electric current inside the coil, i.e. current (Ampere), resistance (Ohm), inductance (Henry), magnetic saturation (Tesla). A simultaneous monitoring of these four parameters allows not only to optimize the operating point of the coil according to the application in which it is used, but also and above all to monitor the conditions of use in order to prevent failures due to excessive stress and plan appropriately and in advance a possible replacement of the coil before irreversible breakage.

From an operational point of view, the direct reading is that of the current value flowing instant by instant in the coil, carried out by means of a suitable dedicated stage. This stage measures the current absorbed by the load through a Hall effect sensor, maintaining the galvanic separation between the high voltage part where the current to be measured flows and the low voltage part where the measured signal is processed, so as to allow the connection of the microprocessor.

The measurement provides a series of parameters that allow the system to constantly monitor the waveform trend, detect any overcurrent and calculate the RMS value of the absorbed current.

The extreme rapidity of response of the measurement section combined with an expert microprocessor management builds a robust protection against short circuits or over-absorption on the load, limiting possible damage.

The technology used allows effective countermeasures to be applied to the known susceptibility to external magnetic fields, intrinsic to the measurements based on the Hall effect. The measurement is insensitive to any power cables that are accidentally found nearby the controller as the sensor used uses an architecture suitable for the purpose.

The other operating parameters would be deduced indirectly or by interpolation with other quantities. The operating voltage would allow to obtain the ohmic resistance value of the coil or by means of real-time calculations carried out by the controller microprocessor according to suitable physical formulas and appropriately stored correction reference tables.

The correlation between the different quantities would allow, as already said, to find the optimal operating point of the system moment by moment and to monitor its vital parameters according to these principles.

The correlation between the supply voltage and the supplied current provides the ohmic resistance value of the coil; this value, compared instant by instant with that declared by the manufacturer, provides an index of the coil consumption, and therefore of its remaining life cycle. In fact, the continuous passage of current, especially if excessive compared to the real need, causes a degeneration of the copper conductor, to the point of causing local fusions of the conductor which can cause short circuits in the coil windings. These short circuits consequently reduce the number of useful turns of the coil itself and consequently, more or less evidently, the performance. Therefore, this ohmic resistance parameter is a first index of the state of wear of the coil.

The most important parameter, to which the direct reading is dedicated, is as mentioned the value of the current delivered. As mentioned above, it allows obtaining the ohmic resistance value, but it also allows deducing another important operating parameter such as the magnetic saturation value. This parameter in fact provides a reading of the efficiency of use of the coil; the more this parameter measured in Tesla is close to the saturation value for the overall coil-induced magnetic system, the less the influence that an increase in current has on the coil performance. This means that when magnetic saturation is reached, the coil is no longer able to deliver greater thrust to the parts fed in the event of a further margin of power delivered by the command signal. Therefore, a reading of this parameter allows a double interpretation: knowing the working efficiency of the reel, then any residual margin before saturation to increase system performance; avoid unnecessary damage to the coil by unnecessarily supplying additional current when saturation is reached, thus preserving the coil itself and avoiding fusions and therefore short circuits.

The last operating parameter that can be obtained from the direct reading of the current is that of the magnetic induction of the coil-induced system. This parameter, measured in Henry, allows deriving the appropriate air gap between the coil and the armature thus facilitating the calibration operations of the vibrating drive and at the same time providing feedback on the efficiency of the system itself; in fact, an incorrect air gap can limit the performance of the system or, if excessive, cause a high consumption of the coil in an attempt to obtain the desired thrust.

The improvement of the performance and diagnosis of the operating status of a vibrating feeder compared to the current state of the art is based on a comparison between the measurement of the magnetic flux density Bm and the reference saturation limit value Bsat of the ferromagnetic material that characterizes from time to time the system in question according to the specific electromagnet in use.

The electromagnetic diagnostic activity is based on the value assumed, during this operation, by the threshold:

ε₁=Bₘ−Bₛₐₜ

Having fixed the limit value of magnetic saturation of the material, according to technical literature, expressed by means of the magnetic flux density parameter Bsat, an efficient operating situation of a vibrating feeder is described by the condition:

ε₁>0

that is, by maintaining the magnetic induction parameter Bm at a constant value lower than Bsat, by means of an automatic negative feedback control that follows the trend of the current I variable over time.

A ferromagnetic material, subjected to an external magnetic field H, has the property of magnetizing itself until reaching a saturation condition, described by the limit value of magnetic induction Bsat. Normal operation of the electromagnet is described by the correspondence between the intensity of the magnetic field Hm, distributed in the material with flux density Bm to determine the working point L. The permeability, or the aptitude of this material to magnetization, described by the relationship

μ=B/H

and high for values of H→0, decreases linearly as H increases and, only after passing a transition region, knee, tends to decrease with a non-linear rule: the magnetic saturation condition means that the flux density in the material Bm no longer increases in proportion to the increase of magnetic field strength H, but settles at the Bsat value. In such conditions, with the increase in electrical power and, therefore, in current, the electromagnet does not develop additional force, while the copper winding tends to heat up beyond its due.

The anomaly situation, signaled by the reaching and possible exceeding of the threshold value:

ε₁≥0

diagnoses an electromagnetic problem and requires the device to be turned off to avoid the risk of melting the protective sheath of the copper conductor in the winding and related short circuit of the turns. It will therefore be advisable to check the distance of the air gap and, if the problem persists when the system is restarted, the coil body must be replaced.

In case of efficient operation, however, this procedure allows to identify the correspondence between the electrical power involved and the indication on the density with which the magnetic flux is distributed in the magnetic path from the core to the armature, in relation to the current consumption: once the consistency between the indicated electrical and electromagnetic parameters has been established, a controller will be able to continue all the other diagnostic activities foreseen on the vibrating device, maintaining its normal operating condition.

The electromechanical diagnostic activity consists in the integration of the electromagnetic diagnostic procedures and the monitoring of the mechanical parameters, channel acceleration and operating frequency, and has the aim of signaling to the operator the impossibility of increasing the conveyance speed of the articles, in case of reached saturation of the magnetic induction in the core material in the electromagnet. The two calculation procedures previously described, both based on electrical measurements of voltage and current and, therefore, of inductance, at the ends of the solenoid, are based on the value assumed by the threshold:

ε₁=Bₘ−Bₛₐₜ

Under efficient use conditions, ε₁<0, the procedure allows the normal variation of the acceleration parameter a0, set on the operator panel of the electronic control. Vice versa, upon reaching and exceeding the threshold, ε₁≥0, the variation of parameter a0 is forbidden to the operator to whom a malfunction alarm of the vibrating device in question is signaled.

The possible processes of analysis of the current I flowing in the copper winding of the electromagnet, coil, allow calculating the variable inductance value L of the magnetic circuit consisting of the copper winding, coil, and the ferromagnetic core/armature assembly.

By inductance L we mean the physical quantity that relates the electrical voltage parameter v, induced at the ends of an inductor, such as the copper winding of the electromagnet on which diagnostic monitoring is carried out, traversed by current I0.

The physical and geometric characteristics of the electromagnet are known, in terms of the number of turns of the copper winding and of the surface of the ferromagnetic core subjected to the phenomenon of magnetization, the electromagnetic response of the vibrating unit under examination and also the mechanical response regarding its oscillation harmonic can be traced back to the measurement of the variation over time of the current parameter I0 flowing in the coil, by calculating the inductance L.

From the variation of current I0 and, therefore, of inductance L, it is possible, in fact, to verify the state of magnetic flux density in the electromagnet and the eventual achievement of the magnetic saturation condition in the material of which it is constituted; at the same time, it is also possible to describe the real harmonic oscillation of the vibrating feeder, by deduction of the air gap parameter, which varies between minimum and maximum values; from the actual air gap excursion and known the operating control frequency of the apparatus in question, it is possible to obtain the acceleration aS to which the transport channel mounted on a linear vibrating feeder or the selection container on a vibrating feeder is subject circular.

The regular operation of a vibrating feeder, which is based on the physical phenomenon of mechanical resonance, provides that in the core-induced magnetic circuit the variation of current I0 and, therefore, of inductance L, follow a non-linear trend during the harmonic movement; since the inductance parameter L is closely related to that of magnetic reluctance, which quantifies in the electromagnet the opposition to the transit of the induced magnetic flux, a maximum inductance value is recorded at a minimum current value. A minimum reluctance value corresponds to a maximum inductance value; it follows a maximum magnetic flux and its maximum density Bm in the material. In this way, the minimum air gap in the mechanical oscillation described corresponds to the maximum attraction between the core and the armature.

In summary, as the inductance parameter increases, the circulation of the magnetic flux between the core and the armature increases, until the magnetic saturation condition is reached, followed by the limitation in the supply of electrical power to the electromagnet and the management of an alarm of malfunction.

Conversely, a maximum current value corresponds to a minimum inductance value, a maximum magnetic reluctance value and a minimum magnetic flux which tends to reduce, until it becomes zero, upon reaching the maximum displacement of the armature with respect to the core. An air gap value that is too high leads to a reduction in the attractive power of the electromagnet, at the expense of an increase in electrical current consumption, a condition monitored by the thermodynamic diagnostic control, constantly active on the controller.

Considering the physical law of the inductor:

v(t)=L(∂i(t))/∂t

it is possible to obtain the inductance parameter according to different implementations on the controller hardware card.

For example, two different processes are indicated, both based on the acquisition of the electrical current signal I0:
process of sampling the I0 signal;
process of balancing the amount of electric charge;
I0 signal sampling process.

$${[ L ( t ) ]}_{{t}_{0}} = \frac{{\int }_{0}^{{t}_{0}} v ( t ) \partial t}{i ( {t}_{0} )} , con {t}_{0} ∈ {T}_{k}$$

The electric current signal I0 is sampled with period Tk; the inductance is obtained from the relationship between the integral of the supply voltage ViTk, computed between the start of the measure (t=0) and the time instant to which the sampling is referred (t=t₀, con t₀∈Tk) and the width of the current sample ITk, also referred to the time instant (t=t₀,con t₀∈Tk). The inductance L is defined precisely and, starting from a constant value L0, corresponding to the manually set air gap, it varies between a minimum value Lmin, at maximum air gap, and a maximum value Lmax, at minimum air gap, during the normal harmonic oscillation of the induced in the vibrating unit.

Process of balancing the amount of electric charge.

Starting from a supply voltage signal Vi:
constant, if applied to the input of an A-B pulse width modulator (PWM, which uses IGBT);
variable, if applied to the input of a phase divider C-D (or thyristor, which uses TRIAC);

distinguishes between:
the current intensity supplied by the electrical network to the electromagnet coil (IA or IC) and the current intensity released by the coil in the electromagnet to the electrical network (IB or ID);
the amount of electric charge supplied by the mains to the coil in the electromagnet (QA or QC), integrating the current signal (IA or IC) in the half-period [0; T/2];
the amount of electric charge released by the coil in the electromagnet to the power grid (QB or QD), integrating the current signal (IB or ID) in the half-period [T/2; T];
the difference between the two quantities of electric charge thus calculated (Q=QA−QB or Q=Qc−QD), responsible for the actual movement of the vibrating unit and generating mechanical and magnetic losses;
the intensity of IT current responsible for the actual movement of the vibrating unit and generating mechanical and magnetic losses, obtained with a derivation operation in the period T of the amount of actual electric charge Q previously calculated.

Finally, dividing the power supply voltage ViT integrated in the period T by the current intensity IT, we obtain an average inductance value KLT over the period T itself.

From the physical-mathematical point of view, the concept of magnetic attraction in a magnetic circuit originates from an analogy with the domain of electric circuits, in particular based on the equivalence between Ohm's Law, valid for electric circuits, and Hopkinson's Law, valid for magnetic circuits. According to Hopkinson's law, the circulation of a magnetic field H along any closed line which concatenates the circuit traversed by current N times is equal to the product of the turns of the winding N for the current I0 passing through them; this quantity is defined magnetomotive force f.m.m.:

f.m.m.=NI₀= [symbol] H·dl=Rₘϕ

Similarly, to Ohm's Law I valid for electrical circuits, V=RI:
the electric voltage V, expressed in Volts, corresponds to the magnetomotive force f.m.m., expressed in Ampere-turns;
the electric current I, expressed in Ampere, corresponds to the magnetic flux, expressed in Weber or Wb;
the electrical resistance R, expressed in Ohm, corresponds to the reluctance Rm, expressed in H⁻¹, which quantifies the opposition in the magnetic circuit to the transit of a magnetic flux;

The total reluctance Rm of the closed magnetic circuit between the core and the armature is obtained from the number of turns H of which the winding is composed and the inductance value L0 variable over time together with the current:

$${R}_{m} = \frac{{N}^{2}}{{L}_{0}}$$

From the Hopkinson Law, the magnetic flux is obtained:

$$ϕ = \frac{{NI}_{0}}{{R}_{m}}$$

and, knowing the section S of the ferromagnetic core crossed by the magnetic flux itself, the magnetic flux, or magnetic induction, density value Bm is obtained, expressed in Tesla or Weber/m\hat{ }2:

$${B}_{m} = \frac{ϕ}{S} [ T ]$$

Similarly to the II Ohm's Law valid for electric circuits, neglecting the reluctance in the ferromagnetic material, it is possible to take the reluctance of a magnetic circuit to the one in the air gap only, according to the relationship:

$$R = ρ \frac{L}{A} {R}_{m} = \frac{{X}_{0}}{{μ}_{0} S}$$

Resistivity ρ, expressed in Ohm×m, corresponds to the reverse of the magnetic permeability of vacuum, μ₀=4π×10⁻⁷, expressed in Henry/m, certifying the aptitude of the magnetic field to propagate in air.

The length of the copper conductor L, expressed in m, corresponds only to the air gap value, X0, expressed in m.

The section of the copper conductor A, expressed in m\hat{ }2, corresponds to the section of the ferromagnetic core crossed by the magnetic field S, expressed in m\hat{ }2.

The working point P=(X0, L0) is obtained from a measurement of the air gap X0 mechanically set upon assembly of the vibrating feeder, performed using a thickness gauge, and from a relative measurement of inductance L0 relative to this air gap value.

Combining the definitions of magnetic reluctance and inductance referring to a solenoid coupled to a closed magnetic core:

$${R}_{m} = \frac{{N}^{2}}{{L}_{0}} {R}_{m} = \frac{{X}_{0}}{{μ}_{0} S}$$

a relationship is obtained between inductance, air gap and characteristic parameters of the copper winding, number of turns N and of the ferromagnetic core with magnetic surface S:

L₀X₀=N²μ₀S=constant

From this hyperbolic trend relationship, to demonstrate the non-linearity existing between the parameters of inductance L and air gap X0 described above and obtained by measuring the current IC the maximum and minimum inductance values, the corresponding values of minimum air gap and maximum:

$${X}_{min} = \frac{{N}^{2} {μ}_{0} S}{{L}_{max}} {X}_{max} = \frac{{N}^{2} {μ}_{0} S}{{L}_{min}}$$

The oscillation value useful for computing the acceleration, therefore, is:

$${X}_{s} = \frac{{X}_{max} - {X}_{min}}{2}$$

from which, knowing the operating frequency f of the vibrating system, the estimation of the acceleration is computed to which the transport channel is subjected:

$$AS = \frac{{X}_{s} \cdot 4 {π}^{2} \cdot {f}^{2}}{9.81} [ g ]$$

Finally, by operating a control in negative feedback, it is envisaged to implement the maintenance of the acceleration parameter AS, with respect to the set-point parameter A0 set manually on the controller, until the appropriate alarm signal is issued, upon reaching the condition of magnetic saturation in the electromagnet material, as required by the electromagnetic diagnostic procedure described above.

A complete analysis, if all the electrical, mechanical and geometric parameters of the vibrating feeder required by the physical-mathematical model in question are known, is accompanied by an approximate reading of the monitoring results, if, on the other hand, the manufacturer does not provide complete manner, for example for reasons of corporate privacy, the technical information characteristic of the components of the vibrating power supply system. For example, it is possible to obtain the approximate value of magnetic induction Bm from the simple measurement of current I0 and referred to a measurement of the maximum size of the electromagnet. In this case, the diagnostic activity must consider appropriate calculation tolerances and it is necessary to report to the maintenance operator that the control of the vibrating feeder is performed on the basis of parameters inferred in an approximate manner.

The proposed monitoring and diagnostic activities described can be applied in a generic way to existing vibrating feeders, built and already installed, or to new concept models.

The processes described in this document are only two of the possible processes that can be implemented to implement the comparison between Bm and Bsat and the analysis of the current I to obtain the inductance L.

1.-6. (canceled)

7. A process for estimating the residual life of a vibrating feeder of articles, the vibrating feeder comprising:
at least one electromagnet driven by a control circuit to make at least one element of the feeder vibrate in frequency, the electromagnet comprising a coil;
the control circuit, with fixed or multiple channel and fixed or variable frequency, comprising, mutually operatively connected:
a Hall effect sensor;
a differential amplifier;
a comparator; and
an integration circuit for controlling the speed and displacement of a power supply element,
the control circuit comprising a dedicated stage suitable for maintaining a galvanic separation between a high voltage part where measured electric current flows and a low voltage part of a signal processed to measure, moment by moment, the absorbed current and the operating voltage of the at least one electromagnet,
the process comprising the following steps:
constantly monitoring the waveform trend of the absorbed current I and the operating voltage V to calculate an ohmic resistance value of the at least one electromagnet, to be compared with a reference value;
determining a residual margin before the magnetic saturation of the at least one electromagnet, a reading of an operating parameter obtained from a direct reading of the current allowing to know the working efficiency of the reel, then any residual margin before saturation to increase system performance;
determining an air gap, through the operating parameter obtained from a direct reading of the current, namely a magnetic induction of the feeder, the parameter allowing to derive the appropriate air gap between the coil and the armature thus facilitating the calibration operations of the vibrating drive and at the same time providing feedback on the efficiency of the feeder;
comparing the measurement of the density of a magnetic flux Bm with respect to a reference saturation limit value Bsat of the at least one electromagnet, through a value of the inductance L on the basis of the acquisition of the current value I absorbed;
verifying an efficient operating situation of the vibrating feeder through the condition ε₁=Bₘ−Bₛₐₜ<0;
wherein a correlation between the supply voltage and the supplied current provides the ohmic resistance value of the coil, the value, compared instant by instant with that declared by a manufacturer, providing an index of the coil consumption, and therefore of its remaining life cycle,
the process including the following steps to derive an inductance value L based on the acquisition of the absorbed current value I:
sampling an electric current signal I0 with a period Tk;
calculating the inductance L given by the ratio between the integral of the supply voltage ViTk and the amplitude of a current sample ITk, the integral of the supply voltage ViTk calculated between the start of the measure, t=0, and the instant to which the sampling refers, t=t0, with t0∈Tk, the amplitude of the current sample ITk referred to the instant t=t0, with t0∈Tk, the inductance L and, starting from a constant value L0, corresponding to the manually set air gap, capable of varying between a minimum value Lmin, with maximum air gap, and a maximum value Lmax, with minimum air gap, during the normal harmonic oscillation of the armature in the vibrating feeder;
the process further including the following step to derive an inductance value L based on the acquisition of the absorbed current value I:
calculating the average inductance KLT in a period T given by the ratio between the integral of the supply voltage ViT and the intensity of the current IT, the constant supply voltage Vi, if applied at the input of a pulse width modulator AB of a circuit that has a PWM that uses IGBT, the variable supply voltage Vi, if applied at the input to a phase shifter CD that uses TRIAC, distinguishing between the intensity of current supplied by the electrical network to the coil of the electromagnet IA or IC and the intensity of current released by the coil in the electromagnet to the electrical network IB or ID, distinguishing between the amount of charge electricity supplied by the mains to the coil in the electromagnet QA or QC, integrating the current signal IA or IC in the half-period [0; T/2] and the quantity of electric charge released by the coil in the electromagnet to the mains QB or QD, integrating the current signal IB or ID in the half-period [T/2; T], the difference between the two quantities of electric charge thus calculated Q=QA−QB or Q=Qc−QD being responsible for the actual movement of the vibrating unit generating mechanical and magnetic losses, the intensity of current IT responsible for the effective movement of the vibrating unit generating mechanical and magnetic losses, obtained with a shunting operation in the period T of the actual electric charge quantity Q.

8. The process of claim 7, for operating the vibrating feeder of articles, the process comprising the following steps:
a) starting the power supply;
b) automatically controlling in negative feedback the waveform trend of the absorbed current I;
c) in the event of an anomaly signaled by the reaching and possible exceeding of a threshold value, for which the residual margin before the magnetic saturation of the at least one electromagnet is not respected, stopping the power supply;
d) controlling the gap distance;
e) restarting the power supply;
f) automatically controlling in negative feedback the waveform trend of the absorbed current I;
g) in the event of an anomaly signaled by the reaching and possible exceeding of a threshold value, for which the residual margin before the magnetic saturation of the at least one electromagnet is not respected, stopping the power supply;
h) in the event of an anomaly, replacing the reel body;
i) in the event of an anomaly, restarting the power supply;
j) in the event of an anomaly, automatically controlling in negative feedback the waveform trend of the absorbed current I;
k) in case of efficient operation, identifying the correspondence between the electrical power involved and the indication of the density with which the magnetic flux is distributed in the magnetic path inside the electromagnet, in relation to the consumption of the absorbed current I;
l) in case of efficient operation, controlling all planned diagnostic activities, such as integration of electromagnetic diagnostic procedures and monitoring of mechanical parameters, channel acceleration and operating frequency, to allow the operator to set the normal variation of the acceleration parameter a0.

9. The process of claim 8, the process operating a negative feedback control to maintain an acceleration parameter aS with respect to the parameter of a0 set manually, until the appropriate alarm signal is issued, upon reaching the condition of magnetic saturation of the electromagnet.

10. The process of claim 7, the process using sensors or other detection means such as Hall effect probes, capable of directly measuring the magnetic field flux and therefore allowing to obtain a comparison between Bm and Bsat, accelerometers able to directly measure the acceleration value to which the vibrating feeder is subjected through which it is possible to obtain (L) itself, a sensor used to measure the displacement of the moving components of the vibrating feeder, an instant measure and an average measure on the period of I.
